(19) United States
(12) Patent Application Publication
(10) Pub. No.: US 2025/0231975 A1
(43) Pub. Date: Jul. 17, 2025

(54) CONTEXT-AWARE BUILDING MODEL SEARCH

(71) Applicant: Digs Space, Inc., Vancouver, WA (US)

(72) Inventors: Nicholas DeGroot, Vancouver, WA (US); Ryan Fink, Vancouver, WA (US); Pavan Kamaraju, Vancouver, WA (US); Jason Goetz, Vancouver, WA (US); Ty Frackiewicz, Vancouver, WA (US)

(73) Assignee: Digs Space, Inc., Vancouver, WA (US)

(21) Appl. No.: 18/781,822

(22) Filed: Jul. 23, 2024

Related U.S. Application Data
(60) Provisional application No. 63/620,715, filed on Jan. 12, 2024.

(51) Int. Cl. G06F 16/334; G06F 16/34

(52) U.S. Cl. CPC G06F 16/3347; G06F 16/345; G06F 16/387; G06Q 50/16

(57) ABSTRACT

A search engine for providing intelligent or conversational responses to user queries into a digital building portfolio are disclosed. In embodiments, a search engine receives a user query and query context. The query and query context are processed and used to search into a vector database and knowledge graph database that are generated from data in the digital building portfolio. The results of the search are used to retrieve relevant data from the digital building portfolio, which are then summarized and used to generate an appropriate response. Other embodiments may be described and/or claimed.

### CROSS-REFERENCE TO RELATED APPLICATIONS

This application claims priority to U.S. Provisional Application No. 63/620,715, filed on 12 Jan. 2024, the contents of which are incorporated by this reference as if set forth fully herein.

### TECHNICAL FIELD

Disclosed embodiments are directed to building information systems, and specifically to techniques for generating and updating a 3D model of a building from various information sources.

### BACKGROUND

Construction of a structure such as a house or commercial building involves input and/or contributions from a wide variety of different sources. Structures typically originate with a set of blueprints or similar plans which provide the basic dimensions of the building, and may specify various structural components. Such blueprints or floor layouts may be obtained from any suitable source. The plans, or subsequent documentation from various subcontractors, can also include information about various building systems such as electrical, telecommunications, plumbing including water and sewage, and heating/ventilation/air conditioning (HVAC), to name a few trades. This information may include data on various structures that may not be readily visible in a completed building. This collection of information can also be useful over the life of its associated structure, to assist with maintenance and repairs, as well as aiding any subsequent modifications, renovations, and/or remodeling. As a result, such plans and documentation are typically kept safe so as to be available for the lifetime of the structure. With computer systems becoming ubiquitous, such information can increasingly be stored and managed in a digital format. This effectively creates a digital building portfolio to collect all relevant information about the building, including its construction, subsequent history, and maintenance through the lifetime of the building. Changes to the plans (such as from remodeling or renovations) and/or subsequent documentation may further be updated at any time during the structure's lifetime to ensure that an accurate record of the structure and its associated fixtures is maintained to facilitate any future repairs and/or renovations.

The background description provided herein is for the purpose of generally presenting the context of the disclosure. Unless otherwise indicated herein, the materials described in this section are not prior art to the claims in this application and are not admitted to be prior art by inclusion in this section.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a block diagram illustrating the components of a system for providing a context-aware search into a digital building portfolio, according to various embodiments.

FIG. 2 is a block diagram illustrating the components of the context-aware search engine of FIG. 1, according to various embodiments.

FIG. 3 is a flowchart of an example method carried out by the example system of FIGS. 1 and 2 for providing a context-aware search engine, according to various embodiments.

FIG. 4 is an example method of the operations for how a search may be performed against processed data from a digital building portfolio, according to various embodiments.

FIG. 5 is a block diagram of an example computer that can be used to implement some or all of the components of the disclosed systems and methods, according to various embodiments.

FIG. 6 is a block diagram of a computer-readable storage medium that can be used to implement some of the components of the system or methods disclosed herein, according to various embodiments.

### DETAILED DESCRIPTION

During the lifetime of a building or other structure, a wide array of relevant information may be gathered and retained. This information is typically retained to provide a reference to answer any questions that may later arise about the building or structure. With traditional hard-copy documentation, as is currently known in the construction and building industry, a person would need to spend time reviewing a wide range of documents to answer such questions or obtain necessary information relevant to the building or structure. Even then, the person may miss relevant information for a variety of reasons: incomplete records, different document versions that omit data found in other versions, and/or inability to understand some types of documents (e.g. blueprints or structural diagrams), to name a few possible explanations. In some cases, relevant information may be generated during the course of a building's construction, e.g. the rationale for why various decisions are made, which may have never been captured in the first instance or may not have been retained in a paper copy.

A digital building portfolio can provide a convenient single repository of information about a structure or building, and may further be generated using tools that automatically capture the history of the building, including any discussions between contractors, subcontractors, architects, owners, etc., involved during construction. The digital building portfolio may further allow for convenient tracking of maintenance calls, remodels, renovations, service visits, etc., for various systems and components of a subject structure or building. For example, a digital building portfolio may have reference information about an appliance that includes any necessary supplies or consumables, and may provide a means to reorder the supplies or consumables. The system hosting the digital building portfolio may track actions of a user taking advantage of such means, and thereby automatically log consumable use and replacement dates.

This repository of digital information may thus be able to answer a variety of different questions that may arise about the subject structure or building. In embodiments, a search engine is incorporated into the digital building portfolio or its hosting system, which can allow natural language searching into the repository of building information to provide answers to user queries. In some instances, the search engine may employ machine learning, such as artificial intelligence in the form of various types of artificial neural nets, and/or other suitable types of machine learning, which can facilitate multi-modal queries (i.e. accepting a variety of different input types, such as text, sound, and/or image queries). Furthermore, the use of machine learning, and in particular, generative AI in some instances, can enable answers beyond simple results to searches, and instead provide responses in a more conversational form. For example, a user may be able to ask questions such as “Which bedrooms have a ceiling fan” or “Can a ceiling fan be installed in any room?”, and obtain an answer from the search engine that directly responds to the question based on the information contained in the digital building portfolio. Other possible functionality and embodiments will be discussed herein.

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

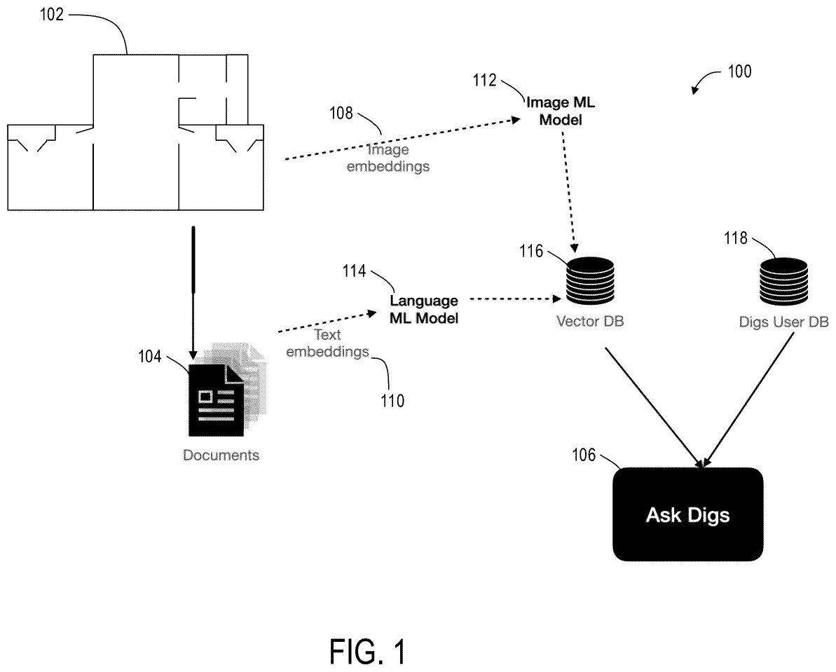

FIG. 1 illustrates, in an example embodiment system 100, possible components to provide a context-aware search for a digital building portfolio. The digital building portfolio comprises a corpus of data related to a subject structure, such as an existing building or building to be constructed, and may include any information relevant to the structure that may be generated over the course of the structure's life, from initial planning to ultimate disposition. System 100 includes a set of building plans 102 that represent a building or other structure, one or more documents 104 that are associated with the building or other structure, and a context-aware search engine 106 which is capable of receiving user queries about the building or other structure. As illustrated in FIG. 1, in the illustrated embodiment the building plans 102 and documents 104 are converted into image embeddings 108 and text embeddings 110, respectively. Embeddings 108 and 110 in turn can be fed to or otherwise referenced by respective image machine learning (ML) model 112 and language ML model 114. These ML models 112 and 114 then provide results to be stored into a vector database 116. The context-aware search engine 106 may then search into the vector database 116 as well as a user information database 118 to provide results to a user query that was supplied to the search engine 106.

Building plans 102, in various embodiments, may be any information or media that is suitable for conveying various physical attributes for a building or structure. These physical attributes may include layouts of each floor of the building, structural aspects such as framing plans, foundation layouts, roof plans, building elevations, etc. Some non-limiting examples include blueprints, floorplans, 2D models, 3D models, architectural drawings, and the like. In some instances, the building plans 102 may be in a hard copy format that must first be scanned, photographed, or otherwise digitized prior to use with system 100. In some instances, the digitized building plans 102 may be processed with one or more various image processing algorithms, such as edge detection, object detection, text recognition, and the like, to extract relevant information and enable conversion into an appropriate format for use with a digital building portfolio.

Documents 104, in embodiments, may be one or more documents or similar material containing information that is associated with the building represented by building plans 102. In some instances, such documents may include, but are not limited to, contractor work orders; manuals for operation and/or maintenance of various fixtures, building systems, appliances, and the like; proposals; bids; change orders; maintenance records; maintenance logs; on-line comments and feedback; tracked changes; materials specifications; receipts; invoices; permits and other government or legal documents; and/or any other document or communication that includes information that pertains to the building or structure that is the subject of building plans 102, and may be desired to be kept as part of the building's historical record.

Both the building plans 102 and documents 104 may be updated from time to time, in various instances. For example, if the building or structure is renovated or remodeled after completion, records of revised building plans 102 and associated documents 104 may be made part of the digital building portfolio. Likewise, additional documents 104 may be added over the lifetime of the building, such as when systems or building components are serviced, repaired, or replaced. For example, records of ongoing maintenance of a building's HVAC systems may be added as performed, along with receipts for any materials. Repainting of the building may be documented with receipts and paint colors/paint codes. Structural repairs may be documented with descriptions of the repairs performed, locations, photographs of before and after conditions, and the like.

As seen in the example embodiment of FIG. 1, the building plans 102 and documents 104 may be converted into image embeddings 108 and text embeddings 114, respectively. The respective embeddings, in embodiments, may be vector representations of each of the building plans 102 and documents 104 that can be embedded in a vector space. Embedding representations into a vector space can facilitate the creation of one or more vector indexes, which can provide a more efficient method of searching into the documents 104 and building plans 102, which may be multi-modal in nature, compared to other search approaches such as plain text searches, image searches, etc.

The image embeddings 108 and text embeddings 114 may be generated with one or more suitable machine learning (ML) models, such as image ML model 112 and language ML model 114. The ML models may be configured to convert inputs, such as images (for image ML model 112) and documents (for language ML model 114) into vector representations of the inputs, i.e., image embeddings 108 and text embeddings 110, respectively. Although FIG. 1 depicts the respective embeddings as input into ML models 112 and 114, it will be understood by a person skilled in the art that the embeddings are generated by the ML models, in various instances. Once generated, the vector representations may be embedded into an appropriate vector space. The vector representations, as mentioned above, may be used to generate one or more vector indexes. Although the example system 100 in FIG. 1 illustrates image embeddings being generated from building plans 102, it should further be understood that in some instances, documents 104 may include information in image format that would be processed as image embeddings 108 via image ML model 112.

The ML models 112 and/or 114 may be implemented using any suitable technology, such as one or more artificial neural networks (ANNs) of a suitable type, or another suitable type of ML algorithm. In some instances, image ML model 112 and language ML model 114 may be implemented using a single ML or ANN system. In other instances, image ML model 112 and language ML model 114 may each be implemented using multiple ML or ANN systems, which may be each configured to generate vector representations of specific types of information modes, e.g. PDF files, text files, scans of text documents, CAD files, raster images, vector images, and the like. In some instances, the ML models 112 and/or 114 may be generative AI systems, such as a foundation model or large language model. These models may be trained using a training data set reflective of information found in a digital building portfolio and/or on training data designed to train the ML models 112 and/or 114, to create vector embeddings that accurately capture relevant aspects of the various building plans 102 and documents 104.

The image embeddings 108 and text embeddings 110, once generated, are supplied to the vector database 116, where they can be indexed into one or more vector indexes. These vector indexes facilitate searching into the vector space for images from building plans 102 and/or documents 104, as well as other modes of information, such as documents 104 that are text-based. In some instances, a given document 104 may have multiple forms of information, such as a document with embedded images. Such a document may be processed by both image ML model 112 and language ML model 114, to generate corresponding image and text embeddings that both refer back to the single document. In embodiments, the vector database and any associated vector indexes may include information to refer back to the original source documents/images used to generate the embeddings.

While FIG. 1 illustrates building plans 102 and documents 104 as separate from user information database 118, in various embodiments the user information database 118 contains the building plans 102 and documents 104. In some instances, building plans 102 and/or documents 104 may be supplied to system 100 as input into the respective image ML model 112 and language ML model 114, and then stored into user information database 118 as part of processing the plans and documents. In other instances, the building plans 102 and/or documents 104 may be stored or housed in user information database 118, and retrieved from the database 118 for processing by the ML models.

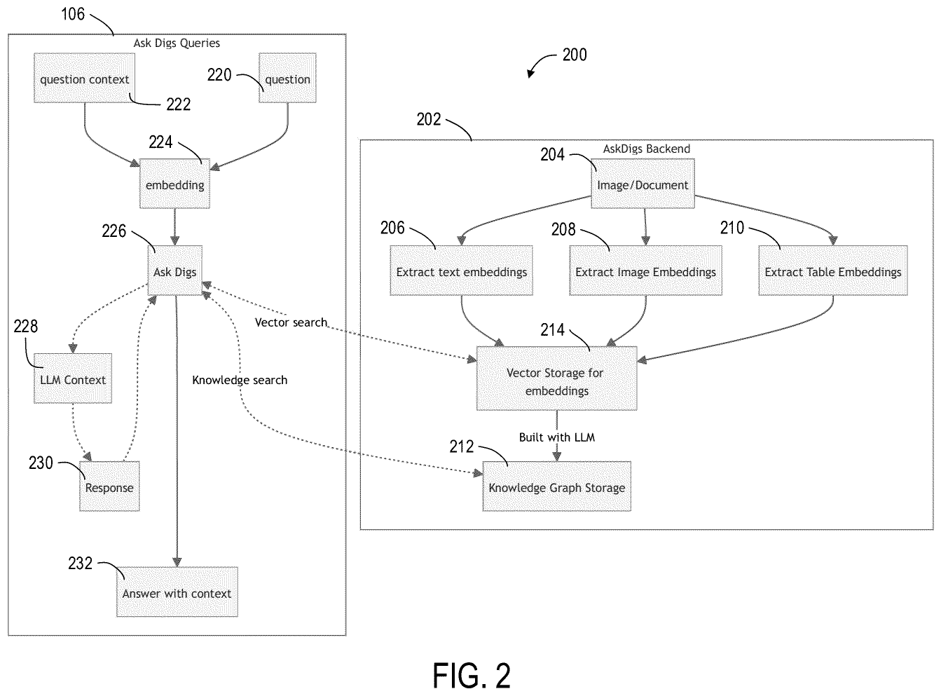

As mentioned above, in embodiments search engine 106, when supplied with a user query, searches into one or more vector indexes associated with vector database 116. The embedding results from the vector data base 116 may then be cross-referenced to the user information database 118 to retrieve the original source documents that created the embeddings that match the user query. Once the results are received by search engine 106, further processing may be carried out to provide a relevant and useful answer to the query, as will be discussed below with respect to FIG. 2.

FIG. 2 is a process flow 200 detailing the operations of an example embodiment of search engine 106 as well as an example embodiment of the flow for a backend 202, which is one possible implementation for generating embeddings of building plans 102 and associated documents 104 and storing them into a vector database, such as vector database 116.

Backend 202, in instances, depicts a process by which the vector database that feeds into the search engine 106 can be generated. In backend 202, embeddings are generated from a collection of images and documents 204. The images and documents 204, in the depicted embodiment, correspond to the building plans 102 and documents 104 depicted in FIG. 1. Each of the images and documents 204 is processed to extract one or more of text embeddings 206, image embeddings 208, or table embeddings 210. This list is not limiting, as in other instances, additional types of embeddings may be extracted depending on the nature of the images and documents 204. In some instances, embeddings may be generated from sound recordings, to name just one possible example. As discussed above with respect to FIG. 1, this processing may be carried out by one or more ML systems, such as one or more ANNs. The generated embeddings may reflect various aspects of each image or document in the collection of images and documents 204. For example, embeddings may reflect aspects such as content, semantic meaning, and syntactic meaning, and the like. The vector space into which the images and documents 204 is embedded will thus capture and allow searching the images and documents 204 based on the captured aspects, e.g. determining which images and documents 204 may be semantically similar. Other embodiments, as will be understood, may capture and allow relating images and documents 204 on different aspects as the needs of a given implementation may require.

Once the embeddings are extracted, they are then stored in a vector storage 214. As described above with respect to FIG. 1, the vector storage 214 may be a version or implementation of vector database 116. As such, vector storage 214 may include one or more vector indexes to facilitate search and retrieval of relevant vector representations of the images and documents 204 in response to a user query. Furthermore, an ML system, which may be implemented using one or more ANNs, may be employed to generate one or more knowledge graphs 212. In some instances, one or more of the ANNs may be graph neural networks. Knowledge graphs 212, in embodiments, may be used in processing user queries such as to help determine context for the query, which may improve accuracy of any query response. As a knowledge graph can encode and/or store the semantics or relationships between various data within a corpus of information, the knowledge graphs 212 may be used subsequently to assist in generating and providing summaries of relevant images and documents 204 that are responsive to the user query, as part of providing a query answer.

As seen in FIG. 2, the knowledge graphs 212 may be generated from the embeddings stored in vector storage 214 by the ML system. Multiple knowledge graphs 212 may be generated in some instances where there may be multiple possible contexts in which to understand data relationships in the corpus of information of a digital building portfolio. In other instances, the knowledge graphs 212 may be generated directly by the ML system or a component of the ML system, such as an ANN which has been trained to analyze the collection of images and documents 204 to ascertain connections between the various images and documents. For example, a knowledge graph 212 generated by an ML system in backend 202 may determine that an uploaded document is a manual for operation of an appliance such as a dishwasher, and so may construct part of a knowledge graph that links the manual to the dishwasher location indicated on the building plans 102 (FIG. 1), which in turn may link to the kitchen room indicated in the building plans 102, which may further link to electrical plans that indicate how the dishwasher is wired, which in turn may link to a particular circuit breaker in the service panel, and so on.

In some instances, the one or more ML systems used to generate the vector representations for embedding and/or the knowledge graphs(s) may comprise a large language model (LLM) at least in part, and/or may comprise any other suitable ML system, such one or more other types of ANNs or generative AI systems. In other instances, the one or more ML systems used to generate the knowledge graph(s) may comprise a graph neural network, which may be separate from the ANN or ML system used to generate the vector representations.

Referring back to FIG. 2, an example instance of search engine 106 may receive a user query in the form of question 220, which may also include a question context 222. The question and question context may be converted into one or more embeddings 224, which may be supplied to a search engine processor 226. The search engine processor 226 may then use the embeddings 224 of the question and question context to search into the vector storage 214, such as via one or more vector search indexes, and/or knowledge graph storage containing one or more knowledge graphs 212. The embeddings 224 of each of the question 220 and question context 222 may be combined together or may remain separate, depending on the specifics of a given implementation of the search engine processor 226. The embeddings 224 may be generated using a similar mechanism as the embeddings 206, 208, and 210. In some instances, this mechanism may comprise one or more ML systems, such as one or more ANNs, as discussed above with respect to FIG. 1.

The question 220 is supplied by a user, such as through a suitable interface. In various instances, the interface may be web-based or application-based, or another suitable mechanism for receiving a query from a user and transmitting it to search engine 106 to form question 220. The question 220 may be in any suitable format, such as a free form or structured text query, image, sound, or the like. In some instances, the question 220 may be multi-modal, including one or more of text, sounds, images, image portions, or the like. The specific modes for question 220 that may be submitted to search engine 106 may depend on the specifics of a given implementation, such as the modes supported by any ML system or module used to generate embeddings 224. Likewise, the ML system or systems used in a given implementation may be selected based on one or more modes desired to be supported by the implementing system.

The context 222 may be determined using a variety of factors. In some instances, the context 222 may include the browsing or interaction history of the user issuing the question 220, such as click and chat history logged from the user's interaction with a platform associated with the search engine 106, user browsing data, previous user queries, and information responsive to the previous user queries, to name some possible sources of context. For example, a user may interact with a digital building portfolio through a website or dedicated application that acts as an interface into the digital building portfolio. The website or dedicated application may log the user's interactions with the digital building portfolio and other aspects, such as chatting with other users who are involved with the building represented by the digital building portfolio. As with question 220, context 222 may be in one or more modes of input, including text, sounds, images, and the like.

The search engine processor 226 may search into the vector storage 214 using any suitable method now know or later developed. For vector storage 214, the question 220 and possibly the context 222 may be converted into vector representations, which may be embedded into the same space employed by embeddings stored in vector storage 214. Such vector representation of question 220 and context 222 may be necessary to carry out a search into the vector index of vector storage 214. For example, in some instances, the vector index may employ a hierarchical navigable small world (HSNW) approach for indexing, which can be searched using an approximate nearest neighbor algorithm. Other instances may use different known or proprietary approaches for searching into the vector storage 214, such as a version of k-nearest neighbors. It should also be understood that, in some embodiments, search engine processor 226 may not carry out the actual search, but rather may submit the search to vector storage 214, which may carry out the search. In some instances search engine processor 226 may be tasked with generating the embeddings for question 220 and/or context 222, while in other instances vector storage 214 may generate the embeddings for question 220 and/or context 222. In still other embodiments, vector storage 214 may be substituted for another type of storage that allows searching into appropriate representations of the various data from the digital building portfolio using a comparable or compatible representation of the question 220 and context 222.

The results of the search into the vector storage 214, in embodiments, may be a list of results whose vectors match or approximately match the vector representation of the question 220, with consideration of context 222. In some instances, the results may be ranked in order of closeness of match to the question 220. The number of returned results may be limited to a predetermined number, provided that the vector storage 214 includes a number of documents or other data that at least equals the predetermined number. Closeness of results may depend upon the particular search algorithm used to search into the vector index of vector storage 214. For one non-limiting example, the extent of matching may be determined based on the distance between the vector embedding of the question 220 and the vector of each returned result. Closeness may reflect similarity as embodied by the vector space into which the images and documents 204 and question 220 are embedded, such as semantic similarity. As will be understood, the search results may comprise vector representations, which in turn may be used to reference the source document or image used to create each vector representation. Thus, results to the question 220 can be provided in a non-vectorized form, if applicable or necessary for subsequent processing.

As can be seen in FIG. 2, the search engine processor 226 may search into both the vector storage 214, as discussed immediately above, and into the knowledge graphs 212 in the knowledge graph storage. The knowledge graphs 212 may allow for retrieval of data within the corpus of information for a digital building portfolio that is related to the various results returned from the search into the vector storage 214. For example, as mentioned above, searching into a knowledge graph 212 for a dishwasher may return the dishwasher's manuals, as well as information about the room in which the dishwasher is installed (kitchen), and possibly other related information, such as wiring runs, breaker identification, water lines, etc. Depending on the nature of the question 220, this information from the knowledge graph 212 can form a context for providing a more accurate and complete answer.

The results from the vector search and knowledge graph search, along with the question context 222 and possibly the question 220, may be provided by the search engine processor 226, in embodiments, to an ML system to obtain a context 228. In the depicted embodiment of FIG. 2, the context 228 is generated by a LLM, which can summarize the results of the vector search, knowledge graph search, and question context 222. In other embodiments, any suitable ML system (including one or more ANNs) may be employed to obtain the summarized results, which form a response 230. The ML system generating the context 228 may be trained to provide a summary of provided input. Summarization techniques are known in the art, and any suitable summarization technique now known or later developed may be employed.

The response 230, which may be a summary of the vector search, knowledge graph search, and/or question context 222, may be returned to the search engine processor 226, which may then generate an answer with context 232 which is responsive to the initial question 220. This answer with context 232 may then be provided to a user interface for providing to a user, or to any other intended target of the results from the question 220.

The nature of the search engine processor 226 may depend on the specifics of a given implementation. In some instances, search engine processor 226 may be implemented using software, which may be part of an implementation of search engine 106. In other instances, search engine processor 226 may be implemented using hardware, or a combination of software, hardware, and/or firmware. To the extent search engine processor 226 may be implemented using hardware, it may be implemented using discrete components, one or more programmable general purpose processors, one or more application-specific processors, an FPGA, ASIC, or some suitable combination of any of the foregoing.

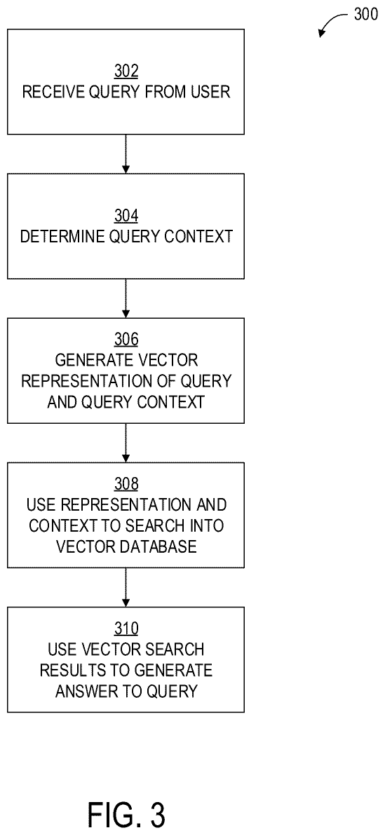

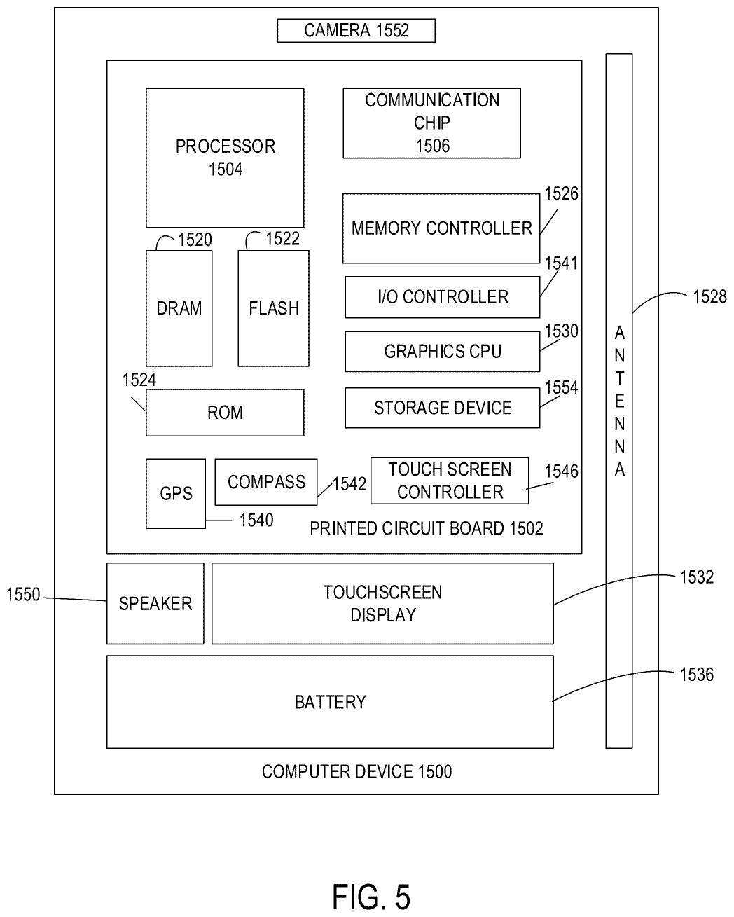

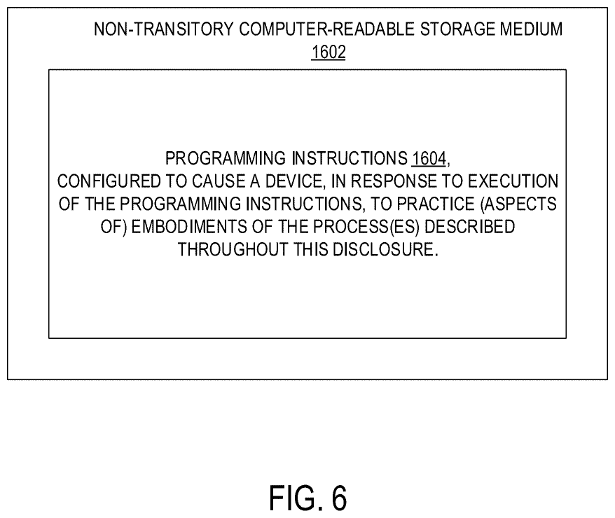

FIG. 3 is an example method 300 of the operations for performing a search into a digital building portfolio, according to various embodiments. The operations of method 300 may be carried out in whole or in part, depending upon the needs of a given embodiment. Further some operations may be omitted, some operations may be added, and the order of operations may be rearranged depending upon the requirements of a given embodiment. The operations of method 300 may be carried out by one or more components of an appropriate system, such as using one or more computer devices 1500 (FIG. 5) and/or executable software, such as depicted in FIG. 6. Some or all operations may be carried out by a server, or by a device within the structure, or both.

In operation 302 of the example method, a query is received from a user. The query may be a question that can be answered with reference to the data of a specified digital building portfolio. In some instances, the user may be a user of an interface to view and/or interact with the digital building portfolio, which may be implemented on a user device such as a mobile device, a laptop, a desktop, a tablet, or the like. In other instances, the user may be a service, program, macro, or other automated system that is configured to interact with a digital building portfolio. The query may be provided directly to a system implementing method 300, such as an instance of system 100, or may be provided by a system remote to the implementing system via a communication channel such as over a network. A user may interact with a digital building portfolio via an interface that accepts user queries such that a query is implicitly directed to the digital building portfolio with which the user is interacting. The query may be a type of question 200, as described above with respect to FIG. 2.

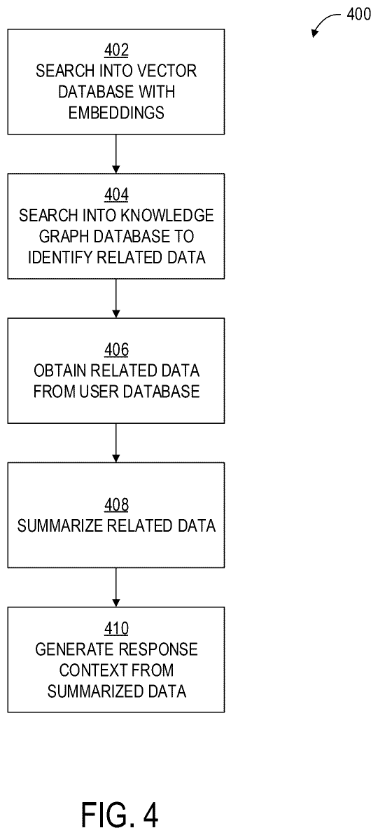

In operation 304 of the example method, a query context is determined. The query context may be a type of question context 222, as described above with respect to FIG. 2. As such, the query context in some instances may include browsing history, history of interaction with the digital building portfolio (including the nature of such interactions), previous queries and answers to the previous queries, and the like. Furthermore, in some instances the query context may also be determined at least in part based on search results obtained from the query as will be described further herein, such as from searching into a knowledge graph database. In such instances, the query context may include documents within the digital building portfolio database that are not directly responsive to the query, but are related to query search results. More specifics of how the query context may be determined in some instances are discussed below with respect to FIG. 4.

In operation 306 of the example method, at least the query is converted into a vector representation that can be embedded into a vector space that is also used for embeddings of digital building portfolio data. These embeddings are discussed in greater detail with respect to FIGS. 1 and 2, described above. In some instances, parts or all of the query context may also be converted into vector representations, if a given implementation determines that searching into the vector database associated with the digital building portfolio will be facilitated by incorporating the query context as part of the search strategy. The vector representations may be generated using one or more ML systems, which may comprise one or more ANNs that are trained to convert queries and associated contextual information into vector representations that can embed into the vector space used in the vector database associated with the digital building portfolio.

In operation 308 of the example method, the vector representation of the query and/or query context is used to search into a vector database that includes embeddings of the data associated with the digital building portfolio. The process of creating the embeddings and vector database are described above with respect to FIGS. 1 and 2. The search may be carried out using any technique suitable for a given implementation of the vector database and associated vector search index, as may be known in the art or later developed. The returned results may comprise a list of vector representations of documents within the digital building portfolio that most closely match the query and/or query context. As will be understood by a person skilled in the art, the results may be ranked in order of relevance or closeness in match to the query and/or query context. Furthermore, the results may include associated non-vector information. In some instances, the non-vector information may include one or more plain text fields that provide user-readable information about each result and/or a key or reference that allows retrieval of the original document used to create the embedded vector representation from the digital building portfolio.

Finally, in operation 310 of the example method, the vector search results are used to generate an answer to the query, which may be delivered to the user via the way in which the query was initially received in operation 302. In other instances, the answer may be delivered via another suitable method. The specifics for how the answer is generated in some possible embodiments will be discussed in greater detail below with respect to FIG. 4.

FIG. 4 is an example method 400 of the operations for how a search may be performed against processed data from a digital building portfolio, according to various embodiments. The operations of method 400 may be carried out in whole or in part, depending upon the needs of a given embodiment. Further some operations may be omitted, some operations may be added, and the order of operations may be rearranged depending upon the requirements of a given embodiment. The operations of method 400 may be carried out by one or more components of an appropriate system, such as using one or more computer devices 1500 (FIG. 5) and/or executable software, such as depicted in FIG. 6. Some or all operations may be carried out by a server, or by a device within the structure, or both.

In operation 402 of the example method, a search engine processor, such as the search engine processor 226 discussed above with respect to FIG. 2, performs a search of one or more vector indexes of a vector database, such as vector database 116 of FIG. 1 or vector storage 214 of FIG. 2. As is known and discussed above with respect to method 300, the search may result in a list of possible matches, which may be arranged in order of relevance or closeness to the search query and/or may be assigned a weight that represents the closeness of match to the search query.

In operation 404 of the example method, the search engine processor may further search into a knowledge graph database, such as the knowledge graph storage discussed with respect to FIG. 2, to obtain a list of documents in the digital building portfolio that are relevant or otherwise related to the search query. In some instances, one or more of the results of the search query from the vector database may be used to search into the knowledge graph database, to return one or more lists of documents in the digital building portfolio that are relevant to each of the search results.

In operation 406 of the example method, the results from the search into the vector database and/or the results from the search into the knowledge graph database may be used to reference into a database containing the data of the digital building portfolio. As discussed above with respect to FIG. 1, this may be a user database, such as user information database 118, that contains building plans, images, and various documents that comprise the digital building portfolio. The vector database and/or knowledge graph database may include entries that can cross-reference the user database to retrieve the original plans, images, and/or documents that were used to generate each entry in the vector and knowledge graph databases, respectively. These entries may comprise a unique key or other ID that is shared between the vector and knowledge graph databases, and the user database, with each unique key or other ID corresponding to a document, image, or plan stored in the user database. With this unique key or other ID, the data in its original form from the digital building portfolio may be retrieved that corresponds to the various results from the search into the vector database and/or knowledge graph database.

In operation 408 of the example method, once the relevant original form data is retrieved from the user database, it may be summarized to form at least part of the response to the query and/or relevant context to inform the response. The data may be summarized using one or more ML systems, which may be trained specifically to summarize data relevant to a building, and more specifically to the types of data that are stored within the user database. The one or more ML systems may be one or more ANNs.

Finally, in operation 410 of the example method, the summaries of the data from the digital building portfolio may be processed or combined to generate the response to the original query, such as the question 220 described above with respect to FIG. 2, and that is received as part of operation 302 of method 300 (FIG. 3). In some instances, this processing may be carried out in whole or in part by an ML system, which may include one or more ANNs, to formulate a response that appropriately matches the original query. In one possible embodiment, the ML system may comprise a generative AI. More specifically, in some instances, the generative AI may comprise a large language model (LLM) that is trained to understand information in a digital building portfolio, and generate responses to questions about the building or structure that is the subject of the digital building portfolio. In still other instances, the LLM may be trained to understand the summaries of the data from operation 408, and use the summaries to formulate an appropriate response to the original query.

FIG. 5 illustrates an example computer device 1500 that may be employed by the apparatuses and/or methods described herein, in accordance with various embodiments. As shown, computer device 1500 may include a number of components, such as one or more processor(s) 1504 (one shown) and at least one communication chip 1506. In various embodiments, one or more processor(s) 1504 each may include one or more processor cores. In various embodiments, the one or more processor(s) 1504 may include hardware accelerators to complement the one or more processor cores. In various embodiments, the at least one communication chip 1506 may be physically and electrically coupled to the one or more processor(s) 1504. In further implementations, the communication chip 1506 may be part of the one or more processor(s) 1504. In various embodiments, computer device 1500 may include printed circuit board (PCB) 1502. For these embodiments, the one or more processor(s) 1504 and communication chip 1506 may be disposed thereon. In alternate embodiments, the various components may be coupled without the employment of PCB 1502.

Depending on its applications, computer device 1500 may include other components that may be physically and electrically coupled to the PCB 1502. These other components may include, but are not limited to, memory controller 1526, volatile memory (e.g., dynamic random access memory (DRAM) 1520), non-volatile memory such as read only memory (ROM) 1524, flash memory 1522, storage device 1554 (e.g., a hard-disk drive (HDD)), an I/O controller 1541, a digital signal processor (not shown), a crypto processor (not shown), a graphics processor 1530, one or more antennae 1528, a display, a touch screen display 1532, a touch screen controller 1546, a battery 1536, an audio codec (not shown), a video codec (not shown), a global positioning system (GPS) device 1540, a compass 1542, an accelerometer (not shown), a gyroscope (not shown), a depth sensor 1548, a speaker 1550, a camera 1552, and a mass storage device (such as hard disk drive, a solid state drive, compact disk (CD), digital versatile disk (DVD)) (not shown), and so forth.

In some embodiments, the one or more processor(s) 1504, flash memory 1522, and/or storage device 1554 may include associated firmware (not shown) storing programming instructions configured to enable computer device 1500, in response to execution of the programming instructions by one or more processor(s) 1504, to practice all or selected aspects of system 100, process flow 200, method 300, or method 400 described herein. In various embodiments, these aspects may additionally or alternatively be implemented using hardware separate from the one or more processor(s) 1504, flash memory 1522, or storage device 1554.

The communication chips 1506 may enable wired and/or wireless communications for the transfer of data to and from the computer device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to IEEE 802.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 1500 may include a plurality of communication chips 1506. For instance, a first communication chip 1506 may be dedicated to shorter range wireless communications such as Wi-Fi and Bluetooth, and a second communication chip 1506 may be dedicated to longer range wireless communications such as GPS, EDGE, GPRS, CDMA, WiMAX, LTE, Ev-DO, and others.

In various implementations, the computer device 1500 may be a laptop, a netbook, a notebook, an ultrabook, a smartphone, a computer tablet, a personal digital assistant (PDA), a desktop computer, smart glasses, or a server. In further implementations, the computer device 1500 may be any other electronic device that processes data.

As will be appreciated by one skilled in the art, the present disclosure may be embodied as methods or computer program products. Accordingly, the present disclosure, in addition to being embodied in hardware as earlier described, may take the form of an entirely software embodiment (including firmware, resident software, micro-code, etc.) or an embodiment combining software and hardware aspects that may all generally be referred to as a “circuit,” “module” or “system.” Furthermore, the present disclosure may take the form of a computer program product embodied in any tangible or non-transitory medium of expression having computer-usable program code embodied in the medium.

FIG. 6 illustrates an example computer-readable non-transitory storage medium that may be suitable for use to store instructions that cause an apparatus, in response to execution of the instructions by the apparatus, to practice selected aspects of the present disclosure. As shown, non-transitory computer-readable storage medium 1602 may include a number of programming instructions 1604. Programming instructions 1604 may be configured to enable a device, e.g., computer 1500, in response to execution of the programming instructions, to implement (aspects of) system 100, process flow 200, method 300, or method 400 described above. In alternate embodiments, programming instructions 1604 may be disposed on multiple computer-readable non-transitory storage media 1602 instead. In still other embodiments, programming instructions 1604 may be disposed on computer-readable transitory storage media 1602, such as, signals.

Any combination of one or more computer usable or computer readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to wireless, wireline, optical fiber cable, RF, etc.

Computer program code for carrying out operations of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

What is claimed is:

1. A method, comprising:
receiving, at a server over a network, a query for a building information model;
determining, by the server, a query context;
generating, by the server, an embedding in a vector space for each of the query, the query context, and data from a database comprising a plurality of building information models;
retrieving, by the server searching into the vector space, information from the building information model responsive to the query; and
providing, by the server, the information responsive to the query, wherein information responsive to the query is part of the building information model.

2. The method of claim 1, wherein the query is a multi-modal query.

3. The method of claim 1, wherein retrieving information responsive to the query from the building information model comprises using the information retrieved from the vector space to query into a database that stores the data from the building information model.

4. The method of claim 1, wherein generating the embedding in the vector space comprises processing the query, the query context, and the data from the building information model through one or more machine learning models.

5. The method of claim 4, wherein the one or more machine learning models further generate a knowledge graph, and determining the query context comprises using the knowledge graph to gather contextual data from the building information model.

6. The method of claim 5, wherein the query context further comprises user browsing data, previous user queries, and information responsive to the previous user queries.

7. The method of claim 1, wherein providing the information responsive to the query comprises generating a summary of the information responsive to the query.

8. A non-transitory computer readable medium (CRM), comprising instructions that, when executed by a processor of an apparatus, cause the apparatus to:
receive a query for a building information model;
determine a query context;
generate an embedding in a vector space for each of the query, the query context, and data from a database comprising a plurality of building information models;
search into the vector space to retrieve information from the building information model responsive to the query; and
provide the information responsive to the query, wherein information responsive to the query is part of the building information model.

9. The CRM of claim 8, wherein the query is a multi-modal query.

10. The CRM of claim 8, wherein the instructions to retrieve information responsive to the query from the building information model are to cause the apparatus to use the information retrieved from the vector space to query into a database that stores the data from the building information model.

11. The CRM of claim 8, wherein the instructions to generate the embedding in the vector space are to cause the apparatus to process the query, the query context, and the data from the building information model through one or more machine learning models.

12. The CRM of claim 11, wherein the instructions are to further cause the apparatus to generate a knowledge graph with the one or more machine learning models, and determine the query context with the knowledge graph to gather contextual data from the building information model.

13. The CRM of claim 12, wherein the query context further comprises user browsing data, previous user queries, and information responsive to the previous user queries.

14. The CRM of claim 8, wherein the instructions to provide the information responsive to the query are to cause the apparatus to generate a summary of the information responsive to the query.

15. A system, comprising:
a storage medium;
a network interface in data communication with a network;
a processor in data communication with the storage medium and network interface; and
instructions stored on the storage medium and executable by the processor, wherein the instructions, when executed, are to cause the system to:
receive, over the network via the network interface, a query for a building information model;
determine a query context;
generate an embedding in a vector space for each of the query, the query context, and data from a database comprising a plurality of building information models;
retrieve, by searching into the vector space, information from the building information model responsive to the query; and
provide the information responsive to the query, wherein information responsive to the query is part of the building information model.

16. The system of claim 15, wherein the query is a multi-modal query.

17. The system of claim 15, wherein the instructions to retrieve information responsive to the query from the building information model are to cause the system to use the information retrieved from the vector space to query into a database that stores the data from the building information model.

18. The system of claim 15, wherein the instructions to generate the embedding in the vector space are to cause the system to process the query, the query context, and the data from the building information model through one or more machine learning models.

19. The system of claim 18, wherein the instructions are to further cause the system to generate a knowledge graph with the one or more machine learning models, and determine the query context with the knowledge graph to gather contextual data from the building information model.

20. The system of claim 19, wherein the query context further comprises user browsing data, previous user queries, and information responsive to the previous user queries.
